(19) United States
(12) Patent Application Publication
(10) Pub. No.: US 2007/0032060 A1
(43) Pub. Date: Feb. 8, 2007

(54) Method for forming conductive wiring and interconnects

(76) Inventor: Ta-Hung Yang, Hsinchu (TW)

Correspondence Address: J C PATENTS, INC., 4 VENTURE, SUITE 250, IRVINE, CA, 92618, US

(21) Appl. No.: 11/197,822

(22) Filed: Aug. 5, 2005

(51) Int. Cl. H01L 21/44

(52) U.S. Cl. 438/597

(57) ABSTRACT

A method for forming conductive wiring is provided. First, a material layer having at least a trench is provided. A conductive material layer is formed on the material layer to fill the trench and cover the top surface of the material layer. A patterned mask layer is formed on the conductive material layer. The conductive material layer not covered by the patterned mask layer is removed. After that, the patterned mask layer is removed.

### BACKGROUND OF THE INVENTION

1. Field of the Invention

The present invention relates to a process for fabricating semiconductor device. More particularly, the present invention relates to a method for forming conductive wiring and interconnects.

2. Description of the Related Art

In the process of manufacturing very large scale integrated (VLSI) circuits, the highly integrated semiconductor devices are connected using more than two layers of interconnects to form a three-dimensional wiring structure.

In general, a multi-layered interconnect structure is fabricated by forming a dielectric layer over a substrate to cover the devices thereon. Then, contacts are formed in the dielectric layer for selectively connecting with the devices on the substrate. After that, conductive lines are formed on the dielectric layer for connecting with the contacts. Because aluminum has a lower resistance, conductive lines are mostly fabricated from aluminum. After forming a single layer of interconnect, the aforementioned process is repeated to form more interconnect layers on top.

With more precise techniques for manufacturing, a few problems are created when the width of the conductive lines is reduced. For example, as the line width is reduced to below 0.28 μm, aluminum conductive wires having a high aspect ratio cannot be formed by patterning a photoresist layer due to intrinsic limitation in the etching process. Furthermore, the micro-particles produced by the etching process may lead to the contamination of the wafer. Since having a smaller line width the current trench and having a lower resistance in the conductive wire are the main targets of semiconductor manufacturers, research efforts aiming to find a method for reducing the line width and producing conductive wires with a lower resistance is currently being made.

### SUMMARY OF THE INVENTION

Accordingly, at least one objective of the present invention is to provide a method for forming conductive wiring having a smaller line width and a lower electrical resistance.

At least a second objective of the present invention is to provide a method for forming conductive wiring capable of producing an interconnect structure having a small line width and a low electrical resistance.

To achieve these and other advantages and in accordance with the purpose of the invention, as embodied and broadly described herein, the invention provides a method for forming conductive wiring. First, a material layer having at least a trench that exposes the areas for forming the conductive wiring is provided. Then, a conductive material layer is formed over the material layer. The conductive material layer fills the trench and covers the top surface of the material layer. The conductive material layer is fabricated using aluminum, tungsten, copper or silver. Thereafter, a patterned mask layer is formed over the conductive material layer. The patterned mask layer covers at least the area of the conductive material layer for forming the conductive wires. After that, the conductive material layer not covered by the patterned mask layer is removed. Finally, the patterned mask layer is removed.

According to the method of forming conductive wiring in the preferred embodiment of the present invention, the conductive material layer comprises forming a metal or metal alloy or plural metal layers or plural metal alloy or a combination of metal and metal alloy.

According to the method of forming conductive wiring in the preferred embodiment of the present invention, the patterned mask layer is fabricated using silicon oxide, silicon nitride or photoresist material comprising semiconductor compound or polymer compound or metal compound, for example.

According to the method of forming conductive wiring in the preferred embodiment of the present invention, the process of forming the conductive material layer includes performing a deposition operation or an electroplating process, for example.

According to the method of forming conductive wiring in the preferred embodiment of the present invention, the process of removing the conductive material layer not covered by the patterned mask layer includes performing an etching operation, for example.

The present invention also provides an alternative method for forming conductive wiring. First, a substrate is provided. The substrate has a plurality of device structures thereon and some of the device structures already have a plurality of corresponding contacts. Then, a dielectric layer is formed on the substrate. The dielectric layer has a plurality of trenches that expose their corresponding contacts. Thereafter, a conductive material layer is formed over the dielectric layer. The conductive material layer fills the trenches and covers the top surface of the dielectric layer. After that, a patterned mask layer is formed over the conductive material layer. The patterned mask layer covers at least the patterned mask layer above the contacts. Then, the conductive material layer not covered by the patterned mask layer is removed. Lastly, the patterned mask layer is removed.

According to the method of forming conductive wiring in the preferred embodiment of the present invention, the conductive material layer is fabricated using aluminum, tungsten, copper or silver, for example.

According to the method of forming conductive wiring in the preferred embodiment of the present invention, the conductive material layer comprises forming a metal or metal alloy or plural metal layers or plural metal alloy or a combination of metal and metal alloy.

According to the method of forming conductive wiring in the preferred embodiment of the present invention, the patterned mask layer is fabricated using silicon oxide, silicon nitride or photoresist material comprising semiconductor compound or polymer compound or metal compound, for example.

According to the method of forming conductive wiring in the preferred embodiment of the present invention, the device structure includes a gate, a doped region or a conductive wire, for example.

According to the method of forming conductive wiring in the preferred embodiment of the present invention, the process of forming the conductive material layer includes performing a deposition operation or an electroplating process, for example.

According to the method of forming conductive wiring in the preferred embodiment of the present invention, the process of removing the conductive material layer not covered by the patterned mask layer includes performing an etching operation, for example.

Because trenches are formed in the dielectric layer and then a conductive material is deposited inside the trench before patterning the conductive material layer into conductive wires, the present invention resolves the problem encountered in the process of forming a conductive wire with a high aspect ratio. Furthermore, using the method in the present invention to operate on the low resistant conductive material (for example, aluminum), conductive wires with a smaller line width and smaller resistance can be produced.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1D are schematic cross-sectional views showing the process for fabricating interconnects according to one preferred embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

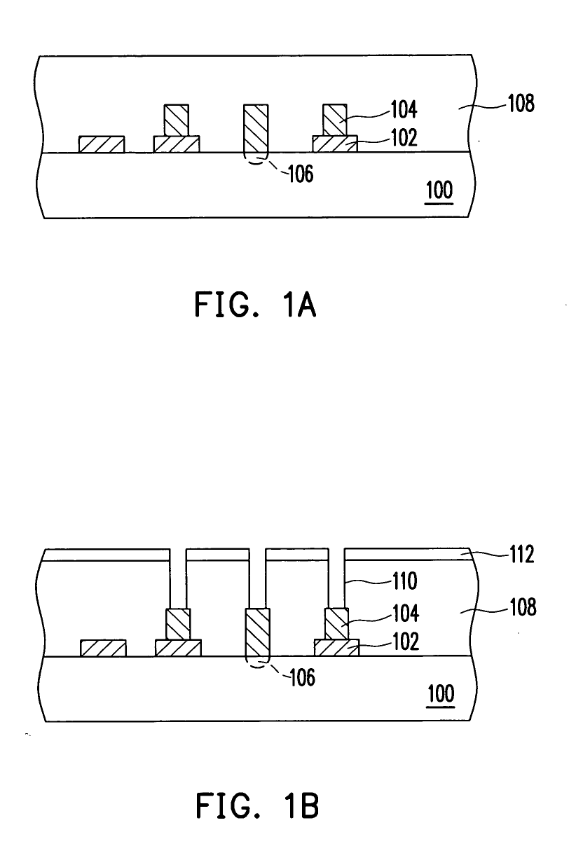

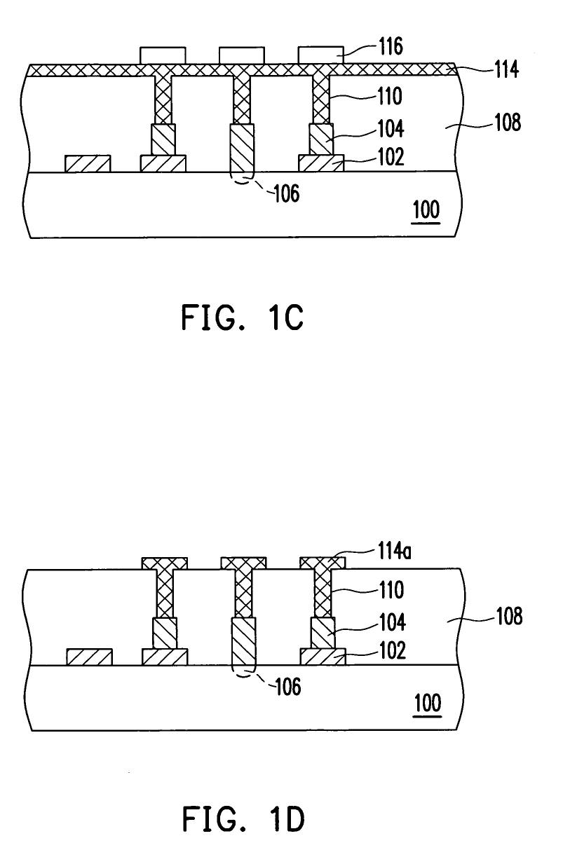

FIGS. 1A through 1D are schematic cross-sectional views showing the process for fabricating interconnects according to one preferred embodiment of the present invention. As shown in FIG. 1A, the method for forming interconnects includes providing a substrate 100. The substrate 100 has a plurality of device structures 102 thereon. Furthermore, a contact 104 is formed on some of the device structures 102. The substrate 100 is a silicon substrate, for example. The device structures can be the gates of transistors or conductive wires. In one embodiment, the contacts 104 may connect electrically with a doped region 106.

Thereafter, a dielectric layer 108 is formed over the substrate 100. The dielectric layer 108 is fabricated using a dielectric material such as silicon oxide. The dielectric layer 108 is formed, for example, by performing a chemical vapor deposition process.

As shown in FIG. 1B, a plurality of trenches 110 is formed in the dielectric layer 108 to expose the corresponding contacts 104. The method of forming the trenches 110 includes, for example, forming a patterned mask layer 112 over the dielectric layer 108. The patterned mask layer 112 exposes the areas for forming the trenches 110. Then, the dielectric layer 108 is etched using the patterned mask layer 112 as a mask to form the trenches 110.

As shown in FIG. 1C, the patterned mask layer 112 is removed and then a conductive material layer 114 is formed over the dielectric layer 108. The conductive material layer 114 completely fills the trenches 110 and covers the top surface of the dielectric layer 108. The conductive material layer is fabricated using a conductive material such as aluminum, tungsten, copper or silver. In one preferred embodiment, the conductive material layer 114 is preferably fabricated using a conductive material with a low electrical resistance. In one preferred embodiment, the conductive material layer comprises forming a metal or metal alloy or plural metal layers or plural metal alloy or a combination of metal and metal alloy. In addition, the conductive material layer 114 is formed, for example, by performing a deposition process or an electroplating process.

Thereafter, another patterned mask layer 116 is formed over the conductive material layer 114. The patterned mask layer covers at least the conductive material layer 114 above the contacts 104. The patterned mask layer 116 is fabricated using a material having an etching selectivity that differs from the conductive material layer 114 such as silicon oxide, silicon nitride or photoresist material comprising semiconductor compound or polymer compound or metal compound.

As shown in FIG. 1D, the conductive material layer 114 not covered by the patterned mask layer 116 is removed to form a conductive wire 114a. The method of removing the conductive material layer 114 not covered by the patterned mask layer 116 includes performing an etching operation, for example, a dry etching or a wet etching process. After forming the conductive wire 114a, the patterned mask layer 116 is removed.

In the present invention, trenches are formed in the dielectric layer and then a conductive material layer is deposited inside the trenches before patterning the conductive material layer into conductive wires. Hence, the present invention is able to resolve the problem encountered in the process of forming a conductive wire with a high aspect ratio. Furthermore, using the method in the present invention to operate on low resistant conductive material (for example, aluminum), conductive wires with a smaller line width and a smaller resistance are produced.

Although the method of forming interconnects is used in the aforementioned embodiment, this should by no means limit the scope of the present invention as such. In other words, the method of forming conductive wiring according to the present invention can be applied to form conductive wires with a high aspect ratio and a low electrical resistance according to the needs of the user and the actual fabricating conditions.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for forming conductive wiring, comprising the steps of:
providing a material layer having at least a trench that exposes the areas for forming conductive wires;
forming a conductive material layer over the material layer, wherein the conductive material layer completely fills the trench and covers the top surface of the material layer, and the conductive material layer is fabricated using aluminum, tungsten, copper or silver;
forming a patterned mask layer over the conductive material layer, wherein the patterned mask layer covers at least the conductive material layer for forming conductive wires;
removing the conductive material layer not covered by the patterned mask layer; and
removing the patterned mask layer.

2. The method for forming conductive wiring in claim 1, wherein the conductive material layer comprises forming a metal or metal alloy or plural metal layers or plural metal alloy or a combination of metal and metal alloy.

3. The method for forming conductive wiring in claim 1, wherein the material constituting the patterned mask layer is selected from a group consisting of silicon oxide, silicon nitride and photoresist material comprising semiconductor compound or polymer compound or metal compound.

4. The method for forming conductive wiring in claim 1, wherein the step for forming the conductive material layer includes performing a deposition process or Electroplating process.

5. The method for forming conductive wiring in claim 1, wherein the step for removing the conductive material layer not covered by the patterned mask layer includes performing an etching operation.

6. A method for forming interconnects, comprising the steps of:
providing a substrate having a plurality of device structures thereon, wherein a plurality of contacts is formed over some of the device structures;
forming a dielectric layer over the substrate, wherein the dielectric layer has a plurality of trenches that expose the contacts;
forming a conductive material layer over the dielectric layer, wherein the conductive material layer completely fills the trenches and covers the top surface of the dielectric layer;
forming a patterned mask layer over the conductive material layer, wherein the patterned mask layer covers at least the conductive material layer above the contacts;
removing the conductive material layer not covered by the patterned mask layer; and
removing the patterned mask layer.

7. The method of claim 6, wherein the material constituting the conductive material layer includes aluminum, tungsten, copper or silver.

8. The method for forming conductive wiring in claim 6, wherein the conductive material layer comprises forming a metal or metal alloy or plural metal layers or plural metal alloy or a combination of metal and metal alloy.

9. The method of claim 6, wherein material constituting the patterned mask layer is selected from a group consisting of silicon oxide, silicon nitride and photoresist material comprising semiconductor compound or polymer compound or metal compound.

10. The method of claim 6, wherein the device structures comprises gates, doped regions or conductive wires.

11. The method of claim 6, wherein the step for forming the conductive material layer includes performing a deposition process or an electroplating process.

12. The method of claim 6, wherein the step for removing the conductive material layer not covered by the patterned mask layer includes performing an etching operation.
